(19) United States
(12) Patent Application Publication
(10) Pub. No.: US 2021/0125959 A1
(43) Pub. Date: Apr. 29, 2021

(54) METAL-COVERED CHIP SCALE PACKAGES

(71) Applicant: TEXAS INSTRUMENTS INCORPORATED, Dallas, TX (US)

(72) Inventors: Masamitsu MATSUURA, Beppu (JP); Kengo AOYA, Beppu (JP); Mutsumi MASUMOTO, Beppu (JP)

(21) Appl. No.: 16/663,089

(22) Filed: Oct. 24, 2019

(51) Int. Cl. H01L 23/00; H01L 23/552; H01L 21/683; H01L 21/78

(52) U.S. Cl. CPC H01L 24/94; H01L 23/552; H01L 21/6836; H01L 2924/3025; H01L 2221/68336; H01L 2221/6834; H01L 21/78

(57) ABSTRACT

In some examples, a wafer chip scale package (WCSP) comprises a die; multiple electrically conductive terminals coupled to a first surface of the die; and a metal covering abutting five surfaces of the die besides the first surface, each of the five surfaces of the die lying in a different plane.

### BACKGROUND

During manufacture, semiconductor chips (also commonly referred to as “dies”) are typically mounted on die pads of lead frames and are wire-bonded, clipped, or otherwise coupled to leads of the lead frame. Other devices may similarly be mounted on a lead frame pad. The assembly is later covered in a mold compound, such as epoxy, to protect the assembly from potentially damaging heat, physical trauma, moisture, and other deleterious factors. The finished assembly is called a semiconductor package or, more simply, a package.

However, other types of packages, such as chip-scale packages (CSP), typically do not include a mold compound covering the semiconductor die. Rather, in many such CSPs, electrically conductive terminals (e.g., solder balls) are formed on an active surface of the die, and the die is then flipped onto an application, such as a printed circuit board (PCB). As a result, an inactive surface of the die is exposed to the environment. This inactive surface of the die is generally successful in shielding the active areas of the die and other electrical connections from harmful influences. Such CSPs—for example, wafer-level CSPs (WL-CSP or WCSP)—are favored for their small size and reduced manufacturing costs.

### SUMMARY

In some examples, a wafer chip scale package (WCSP) comprises a die; multiple electrically conductive terminals coupled to a first surface of the die; and a metal covering abutting five surfaces of the die besides the first surface, each of the five surfaces of the die lying in a different plane.

In some examples, a method of manufacturing a wafer chip scale package (WCSP) comprises positioning multiple electrically conductive terminals on a surface of a semiconductor wafer; positioning the semiconductor wafer on an adhesive layer such that the multiple electrically conductive terminals are in contact with the adhesive layer; singulating the semiconductor wafer to produce a die, the die having at least one of the multiple electrically conductive terminals coupled to a first surface of the die; and covering five surfaces of the die, besides the first surface of the die, with a metal covering, each of the five surfaces lying in a different plane.

### BRIEF DESCRIPTION OF THE DRAWINGS

For a detailed description of various examples, reference will now be made to the accompanying drawings in which:

FIG. 1A depicts a cross-sectional view of a semiconductor package having a light-resistant metal covering, in accordance with various examples.

FIG. 1B depicts a profile view of a semiconductor package having a light-resistant metal covering, in accordance with various examples.

FIG. 1C depicts a top-down view of a semiconductor package having a light-resistant metal covering, in accordance with various examples.

FIG. 1D depicts a perspective view of a semiconductor package having a light-resistant metal covering, in accordance with various examples.

FIG. 2A depicts a cross-sectional view of a semiconductor package having an insulation covering and a light-resistant metal covering, in accordance with various examples.

FIG. 2B depicts a profile view of a semiconductor package having an insulation covering and a light-resistant metal covering, in accordance with various examples.

FIG. 2C depicts a top-down view of a semiconductor package having an insulation covering and a light-resistant metal covering, in accordance with various examples.

FIG. 2D depicts a perspective view of a semiconductor package having an insulation covering and a light-resistant metal covering, in accordance with various examples.

FIGS. 3A-3K and 4A-4C depict various aspects of a process flow for manufacturing a semiconductor package having either a metal covering or a combination of an insulation covering and a metal covering, in accordance with various examples.

FIG. 5 depicts a flow diagram of a method for manufacturing a semiconductor package having an insulation covering and a metal covering, in accordance with various examples.

### DETAILED DESCRIPTION

Despite these advantages of CSPs, in some particular applications, the lack of a mold compound in CSPs causes inadequate protection of the active surface of the semiconductor die from deleterious influences. Specifically, some such CSPs include semiconductor dies with optical circuitry formed on the active surfaces of the dies. The semiconductor material is unable to block certain types of ambient light, such as infrared light, from penetrating the inactive areas of the semiconductor die and propagating to the active areas of the die. When such light reaches the active areas of the semiconductor die, the light interacts with the optical circuitry that is present at the active areas of the die, thereby negatively impacting the performance of the optical circuitry.

Ambient light can damage functionality in other ways. For example, the photovoltaic properties of semiconductors can also cause the semiconductor dies to produce electrical signals in response to ambient light, and these electrical signals can interfere with the signals on the active surface of the die. Back side coats are sometimes used to protect the back side of the die, but the materials typically used provide inadequate protection from ambient light.

This disclosure describes various examples of a novel CSP (e.g., WCSP) that solves the foregoing technical challenges. In some examples, the novel CSP includes a thin metal covering abutting the inactive surfaces of the semiconductor die. The metal covering is composed of a material and is of a sufficient thickness to block light, including infrared light, from penetrating the semiconductor die. This shielding precludes interaction between ambient light and the optical circuitry on the active surface of the semiconductor die, and it likewise mitigates against undesirable photovoltaic effects within the semiconductor. In some examples, a thin insulation covering may be positioned between the metal covering and the semiconductor die. The insulation covering is to facilitate the adhesion between the metal covering and the semiconductor die and to prevent electrical shorts between the metal covering and the active circuit. These examples provide the technical advantages of a small package size and resistance to the negative performance effects of ambient light. This disclosure also describes illustrative manufacturing methods and process flows for manufacturing such CSPs. These and other examples are now described with respect to the drawings.

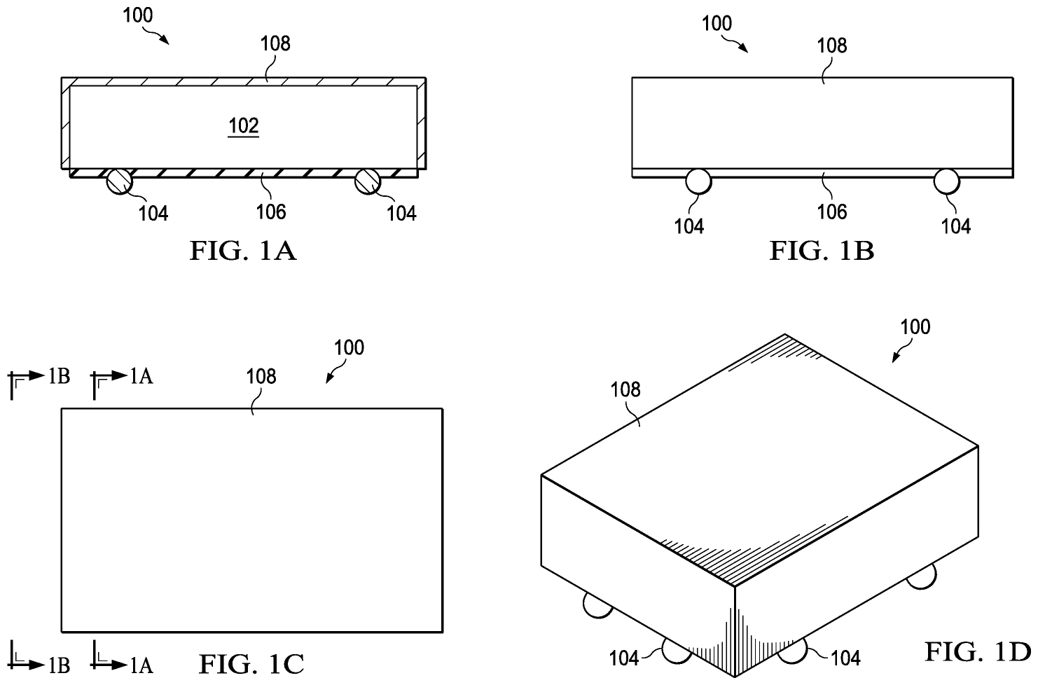

FIG. 1A depicts a cross-sectional view of a semiconductor package having a light-resistant metal covering, in accordance with various examples. Specifically, FIG. 1A depicts a semiconductor package 100. The package 100 is a CSP. For example, the package 100 is a WCSP. Other types of CSPs also may be used. The package 100 comprises a semiconductor die 102. The die 102 may comprise any suitable semiconductor material, such as silicon, for example. In some examples, the die 102 comprises a semiconductor material that is susceptible to light penetration, for example infrared light penetration. The bottom surface of the die 102 is an active surface that comprises circuitry formed thereupon and abuts a miscellaneous layer 106. The miscellaneous layer 106 may comprise any of a variety of materials and sub-layers to facilitate communication between the bond pads of the die 102 and electrically conductive terminals (e.g., solder balls) 104, depending on the application and the specific configuration of the package 100. For example, the miscellaneous layer 106 may comprise dielectrics, polyimides, metal traces, passivation, coatings, etc. The specific composition of the miscellaneous layer 106 is not described in detail herein because it may vary depending on the particular application and because it is not directly relevant to the novel features described herein. In general, however, the composition of the miscellaneous layer 106 is open-ended and is not limited to any particular number, types, or configurations of sub-layers.

The package 100 comprises the aforementioned electrically conductive terminals 104 (e.g., solder balls). Although FIG. 1A only depicts two illustrative terminals 104, any numbers of terminals 104 may be used. The terminals 104 may be of any suitable size, and the terminals 104 are not necessarily spherical. The terminals 104 couple to the active (i.e., bottom) surface of the die 102 via the miscellaneous layer 106, for example, via metal traces in the miscellaneous layer 106 or via a direct connection to active areas of the die 102.

The die 102 comprises multiple surfaces (e.g., six surfaces). Each of the multiple surfaces of the die 102 lies in a different plane. For instance, the bottom surface of the die 102 that abuts the miscellaneous layer 106 lies in a first plane; the top surface of the die 102 that opposes the bottom surface lies in a second plane that is different than the first plane; and each of the four lateral sides of the die 102 lies in a separate plane that is different than the other five planes of the die 102.

In some examples, the package 100 comprises a metal covering 108 that covers five of the six surfaces of the die 102. In some examples, the metal covering 108 does not cover the active, bottom surface of the die 102, but it covers the remaining five surfaces of the die 102 (e.g., the inactive surfaces of the die 102). In examples where the die 102 has a different number of surfaces than six, it may be said that the metal covering 108 covers all surfaces except for the active surface of the die 102. The remainder of this discussion assumes a die 102 with six surfaces, with the bottom surface being the active surface of the die.

In some examples, the metal covering 108 covers each of the five surfaces (excluding the active, bottom surface) entirely (i.e., with no gaps in coverage). In some examples, the metal covering 108 covers a majority (i.e., more than 50%) of each of the five surfaces. In some examples, the metal covering 108 covers at least one surface entirely and the majority of at least one other surface. In some examples, the metal covering 108 covers each of the five surfaces at least partially. In some examples, the metal covering 108 covers the five surfaces with varying combinations of entire coverage, majority coverage, and/or partial coverage, and all such combinations are contemplated and included in the scope of this disclosure. In some examples, the metal covering 108 covers fewer than five surfaces but at least one surface.

In some examples, the metal covering 108 has an approximate thickness of 750 Angstroms (A). In some examples, the metal covering 108 comprises aluminum, copper, gold, titanium, nickel, silver, palladium, or tin. In some examples, the metal covering 108 comprises an alloy, such as a tungsten-titanium alloy or stainless steel. A variety of techniques are usable to position the metal covering 108, including metallic ink printing, sputtering, deposition, electro-less plating, spray techniques, and electroplating, as described below.

FIG. 1B depicts a profile view of the package 100, in accordance with various examples. As shown, the metal covering 108 covers a lateral side surface of the die 102 (with the die 102 not being expressly visible in FIG. 1B). The view of FIG. 1B is representative of the views of the four lateral sides of the package 100.

FIG. 1C depicts a top-down view of the package 100, in accordance with various examples. As shown, the top surface of the package 100 includes the metal covering 108.

FIG. 1D depicts a perspective view of the package 100, in accordance with various examples. As depicted, the top surface of the package 100 and the four lateral sides of the package 100 include the metal covering 108. The active, bottom surface of the die 102 couples to the electrically conductive terminals 104 via the miscellaneous layer 106 (where the miscellaneous layer 106 is not visible from the angle of view of FIG. 1D).

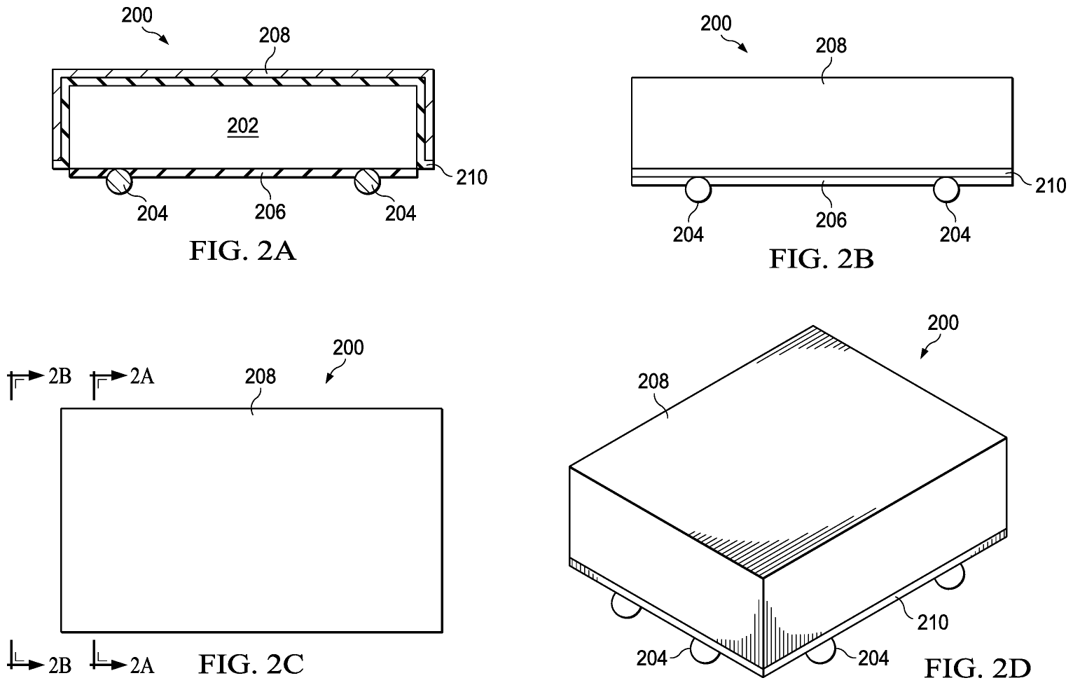

FIG. 2A depicts a cross-sectional view of a semiconductor package having an insulation covering and a light-resistant metal covering, in accordance with various examples. Specifically, FIG. 2A depicts a semiconductor package 200, which comprises a CSP (e.g., a WCSP). The package 200 comprises a semiconductor die 202, electrically conductive terminals 204, and a miscellaneous layer 206. In at least some examples, the semiconductor die 202, the electrically conductive terminals 204, and the miscellaneous layer 206 are similar or virtually identical to the semiconductor die 102, the electrically conductive terminals 104, and the miscellaneous layer 106 of FIGS. 1A-1D, respectively. Thus, the description provided above for elements 102, 104, and 106 also applies in at least some examples to the elements 202, 204, and 206, respectively.

The package 200 differs, however, from the package 100 in that the package 200 comprises multiple layers stacked on the semiconductor die 202—specifically, an insulation covering 210 abutting the semiconductor die 202, and a metal covering 208 abutting the insulation covering 210. In some examples, the insulation covering 210 abuts the various inactive surfaces of the semiconductor die 202 in the same or similar manner as the metal covering 108 abuts the various inactive surfaces of the semiconductor die 102 (described above with respect to FIGS. 1A-1D). Each of the possible configurations and positions for the metal covering 108 to cover the die 102 described above also applies to the insulation covering 210 to cover the die 202. In some examples, the insulation covering 210 is composed of an epoxy or resin, or a substance such as silicon oxynitride (SiON). In some examples, the insulation covering 210 has an approximate thickness of 750 A. As described below, various techniques may be used to position the insulation covering 210, such as deposition or spray techniques.

In some examples, the insulation covering 210 comprises multiple surfaces (e.g., five surfaces). Each of the multiple surfaces of the insulation covering 210 lies in a different plane. For instance, the top surface of the insulation covering 210 that opposes the bottom surface of the die 202 lies in a first plane, and each of the four lateral sides of the insulation covering 210 lies in a separate plane that is different than the other four surfaces of the insulation covering 210. In some examples, the metal covering 208 covers all five of the surfaces of the insulation covering 210. In examples where the insulation covering 210 has a different number of surfaces than five, it may be said that the metal covering 208 covers all such surfaces. The remainder of this discussion assumes an insulation covering 210 with five surfaces. In some examples, the metal covering 208 covers each of the five surfaces of the insulation covering 210 entirely (i.e., with no gaps in coverage). In some examples, the metal covering 208 covers a majority (i.e., more than 50%) of each of the five surfaces of the insulation covering 210. In some examples, the metal covering 208 covers at least one surface entirely and the majority of at least one surface. In some examples, the metal covering 208 covers each of the five surfaces of the insulation covering 210 at least partially. In some examples, the metal covering 208 covers the five surfaces of the insulation covering 210 with varying combinations of entire coverage, majority coverage, and/or partial coverage, all of which are contemplated and included in the scope of this disclosure. In some examples, the metal covering 208 covers fewer than five surfaces of the insulation covering 210 but at least one surface of the insulation covering 210.

In some examples, the metal covering 208 has an approximate thickness of 750 A. In some examples, the metal covering 208 comprises aluminum, copper, gold, titanium, nickel, silver, palladium, or tin. In some examples, the metal covering 208 comprises an alloy, such as a tungsten-titanium alloy or stainless steel. A variety of techniques are usable to position the metal covering 208, including metallic ink printing, sputtering, deposition, electro-less plating, and electroplating, as described below.

FIG. 2B depicts a profile view of the semiconductor package 200, in accordance with various examples. As shown, the metal covering 208 covers a lateral side surface of the insulation covering 210 (with the insulation covering 210 not being expressly visible in FIG. 2B). The view of FIG. 2B is representative of the views of the four lateral sides of the package 200. As this view also depicts, a thin strip of the insulation covering 210 is exposed to the lateral surfaces of the package 200. This strip, which may have a thickness approximately the same as the thickness of the insulation covering 210 more generally, is exposed in this manner because of the process used to manufacture the package 200, as described below. Other examples of the manufacturing process may be used to eliminate the strip if desired, and such examples also are described below.

FIG. 2C depicts a top-down view of the semiconductor package 200, in accordance with various examples. As shown, the top surface of the package 200 includes the metal covering 208.

FIG. 2D depicts a perspective view of a semiconductor package having an insulation covering 210 and a light-resistant metal covering 208, in accordance with various examples. The metal covering 208 covers the surfaces of the insulation covering 210, which, in turn, covers the surfaces of the die 202 (not expressly shown in FIG. 2D) except for the active, bottom surface of the die 202.

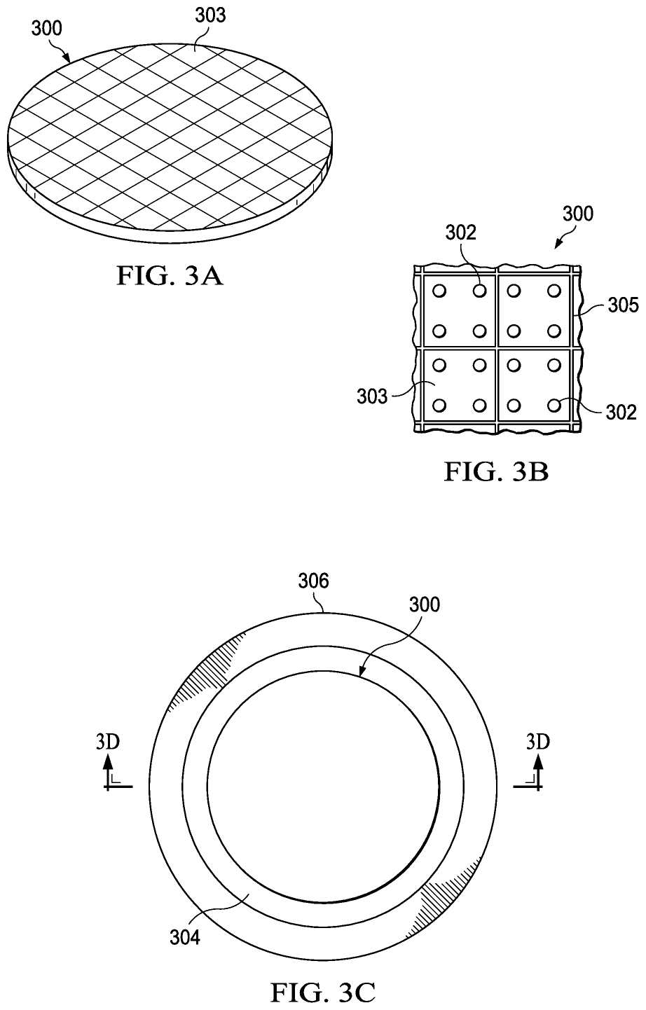

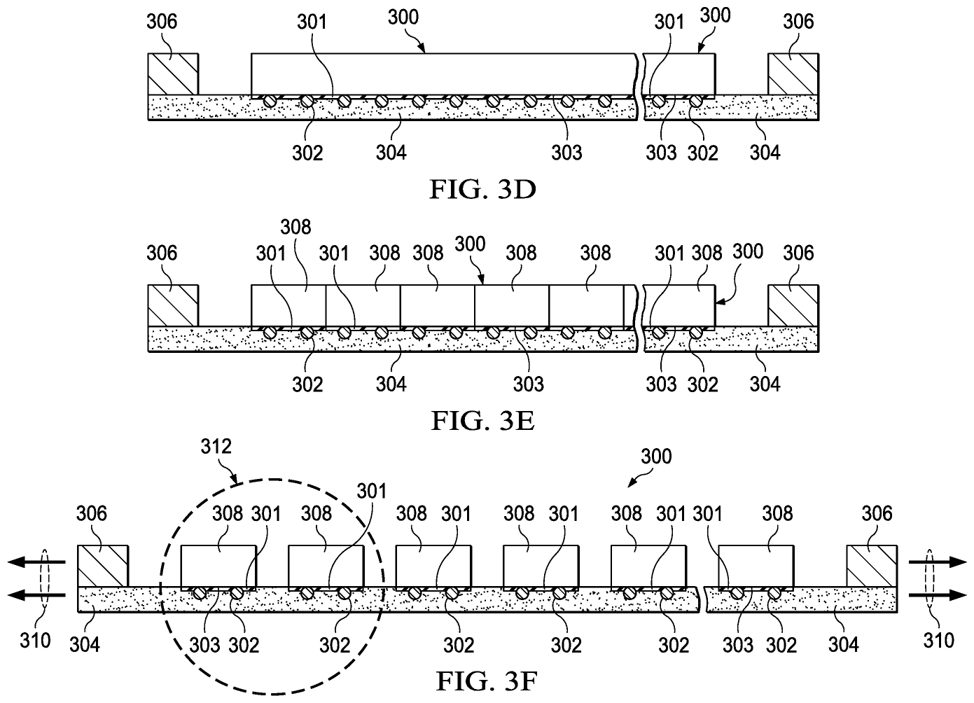

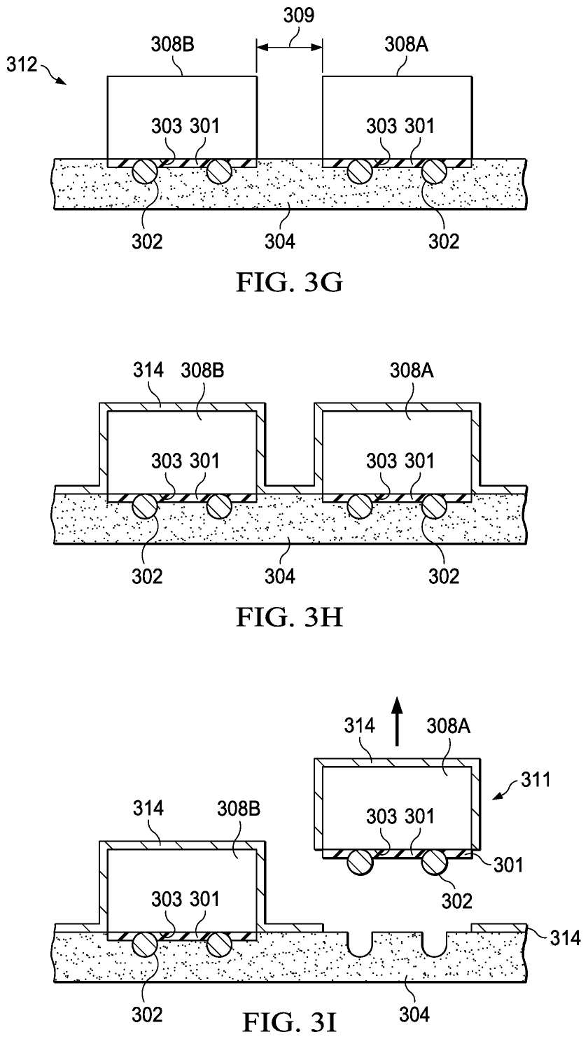

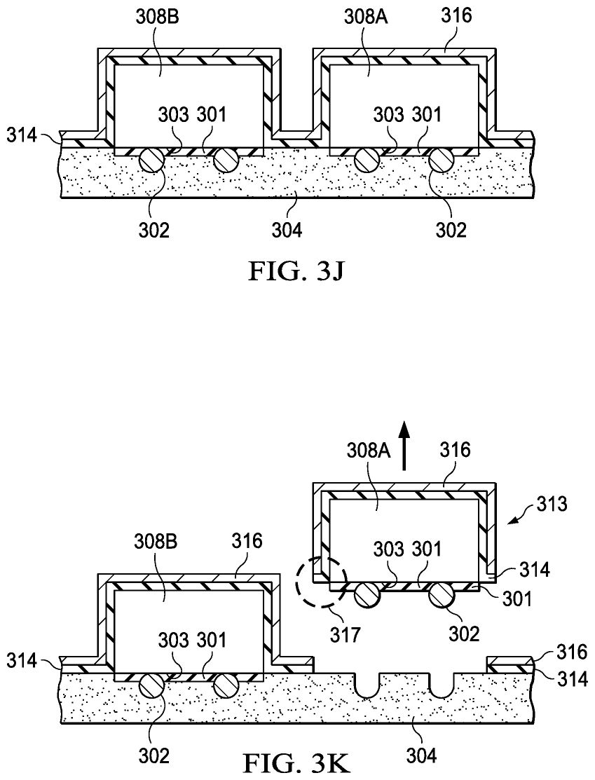

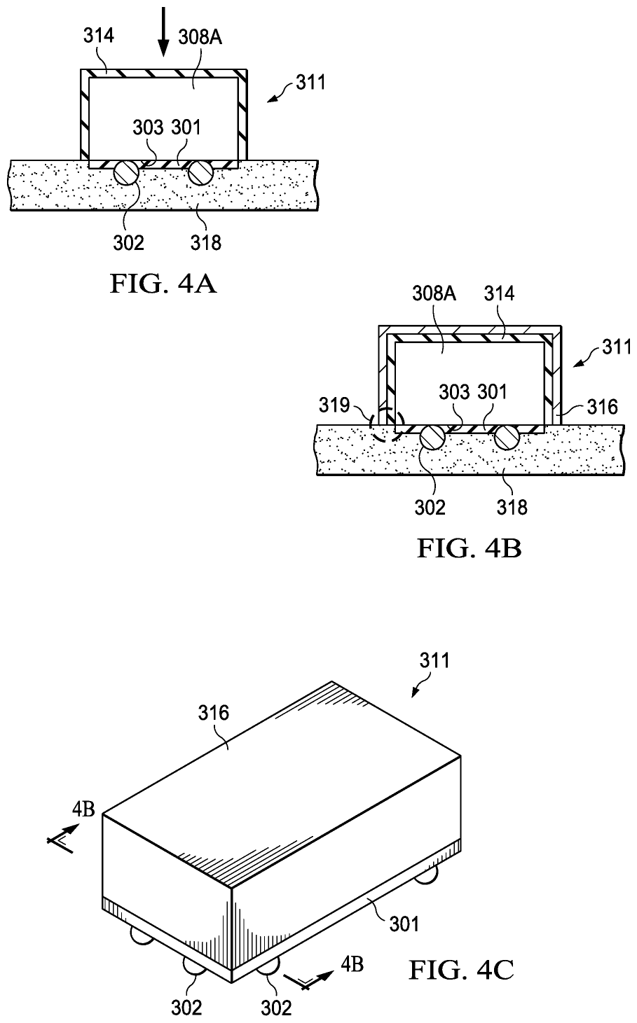

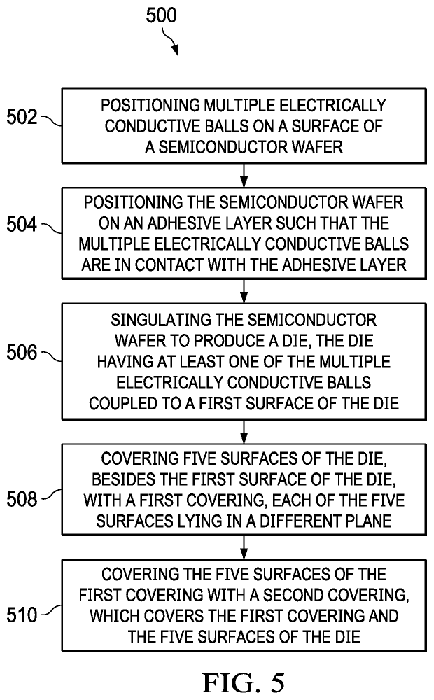

FIGS. 3A-4C depict various aspects of a process flow for manufacturing a semiconductor package having either a metal covering or a combination of an insulation covering and a metal covering, in accordance with various examples. FIG. 5 depicts a flow diagram of a method 500 for manufacturing a semiconductor package having an insulation covering and a metal covering, in accordance with various examples. The method 500 of FIG. 5 is now described in relation to the process flow of FIGS. 3A-4C.

The method 500 begins with positioning multiple electrically conductive terminals (e.g., conductive balls) on a surface of a semiconductor wafer (502). FIG. 3A depicts a perspective view of an illustrative semiconductor wafer 300, and more specifically an active surface 303 of the wafer 300. As the close-up view of FIG. 3B depicts, the active surface 303 of the wafer 300 has multiple scribe streets 305 and multiple electrically conductive terminals 302 formed thereupon. The terminals 302 may be formed with any suitable size, shape, configuration, and density (i.e., pitch). The terminals 302 may be deposited using any suitable technique, such as a brush technique. The active surface 303 may have a plurality of circuits (not expressly shown in FIG. 3B to preserve clarity) formed on it, and the terminals 302 may be deposited directly on these circuits. Alternatively, a miscellaneous layer, such as the miscellaneous layer 106 described above, may be formed on the active surface 303, and the terminals 302 may be formed on that miscellaneous layer. (FIG. 3B omits the depiction of a miscellaneous layer to preserve clarity.)

The method 500 further comprises positioning the semiconductor wafer on an adhesive layer such that the multiple electrically conductive terminals are in contact with the adhesive layer (504). FIG. 3C depicts the positioning of the wafer 300 on an adhesive layer 304 (e.g., a dicing tape). The adhesive layer 304 couples to a flex frame 306. In some examples, the flex frame 306, adhesive layer 304, and the wafer 300 are sized relative to each other so that the post-singulation dies of the wafer 300 may be pulled apart from each other by stretching the adhesive layer 304, as described below. To leave adequate room for this spreading of the singulated dies, in some examples, the wafer 300 occupies no more than 50% of the area of the adhesive layer 304.

In some examples, the wafer 300 is positioned on the adhesive layer 304 with the active surface 303 down, i.e., making contact with the adhesive layer 304. Thus, the surface of the wafer 300 visible in FIG. 3C is the back side of the wafer that is opposite the active surface 303. FIG. 3D depicts a cross-sectional view of the assembly of FIG. 3C. Specifically, FIG. 3D depicts the wafer 300, a miscellaneous layer 301 abutting the active surface 303 of the wafer 300, terminals 302 coupled to an at least partially embedded in the adhesive layer 304, and the flex frame 306.

The method 500 further comprises singulating (e.g., sawing) the wafer to produce a die, the die having at least one of the multiple terminals coupled to a first surface of the die (506). FIG. 3E depicts a cross-sectional view of a singulated wafer 300, which produces a plurality of individual dies 308, each die 308 having at least one terminal 302 coupled to that die 308. After the singulation, the individual dies 308 may be pulled apart from each other by stretching the adhesive layer 304 using an appropriate tool, such as an expander. In some examples, the dies are pulled apart such that the distance between each pair of dies is approximately 30 micrometers (um). By increasing the spacing between the dies 308, the insulation covering and/or metal covering may be properly applied to the various surfaces of each die 308, as described below. In FIG. 3F, arrows 310 depict this stretching action.

Numeral 312 is depicted in both FIGS. 3F and 3G and indicates a close-up view of two illustrative dies 308. As FIG. 3G depicts, the dies 308 now include an expanded spacing (or pitch) 309 between the dies. This expanded spacing facilitates a proper application of the insulation and/or metal coverings, as FIG. 3H depicts. Specifically, FIG. 3H depicts the covering of five surfaces of each of the dies 308 with a first covering 314 (508). The first covering 314 is applied to the five inactive surfaces of each of the dies 308 as well as the area of adhesive layer 304 between the dies 308, as shown. For purposes of this description, the first covering 314 may be a metal covering or an insulation covering. In the event that an insulation covering is not desired in the completed package, the first covering 314 may be a metal covering, and as shown in FIG. 3I, a completed package 311 comprising a die 308A covered by the metal covering 314 may be lifted from the adhesive layer 304 (e.g., using a pick and place machine) and used as may be desired.

However, in the event that an insulation covering is desired in the completed package, the first covering 314 may be an insulation covering, and as shown in FIG. 3J, a second covering 316 (e.g., a metal covering) may be applied to the insulation covering 314 (510). The second covering 316 thus covers the five surfaces of the insulation covering 314 as well as the five inactive surfaces of each of the dies 308. In some examples, the metal covering 316 is applied using a sputter technique, a deposition technique, an electro-less plating technique, or an electroplating technique. In some examples, the metal covering 316 is applied using a printing technique, such that the metal covering 316 is printed using a metallic ink. In the case of metallic ink printing, the metal covering 316 comprises a metallic ink residue (as do, e.g., the metal coverings 108 (FIGS. 1A-1D) and 208 (FIGS. 2A-2D)). As FIG. 3K depicts, a completed package 313 comprising the die 308A covered by the insulation covering 314 and the metal covering 316 may be lifted from the adhesive layer 304.

Still referring to FIG. 3K, numeral 317 indicates a feature of the package 313 that is now described in more detail. Specifically, the feature indicated by numeral 317 includes the insulation covering 314 extending vertically down the lateral side of the die 308A and, upon reaching the bottom surface of the die 308A, extending orthogonal to the vertical run of the metal covering 316 which the insulation covering 314 abuts. This feature is a result of the manner in which the two coverings are deposited and the fact that the package 313 is subsequently lifted from the adhesive layer 304 (compare FIGS. 3J and 3K). This feature 317 produces the strip 210 shown in FIG. 2D. It may be desirable to form this feature or to avoid formation of this feature. If the feature is not desired, FIGS. 3I and 4A-4C depict a process flow to avoid its formation. Specifically, after the package 311 is lifted from the adhesive layer 304 in FIG. 3I, the package 311 is coupled to another adhesive layer 318, with the terminals 302 contacting the adhesive layer 318, as FIG. 4A depicts. The package 311 does not include the horizontal extension of the insulation layer 314 (see numeral 317 in FIG. 3K) because of the manner in which the package 311 is lifted from the adhesive layer 304 in FIG. 3I. Thus, when the metal covering 316 is applied to the insulation covering 314 as shown in FIG. 4B, the metal covering 316 and the insulation covering 314 both extend vertically to the adhesive layer 304. In this way, as 319 indicates, the horizontal extension of the insulation layer 314 is avoided, if desired. The resulting package 311 is covered by the metal covering 316 as shown in FIG. 4C, but unlike the package 200 shown in FIG. 2D, the package 311 lacks the thin strip 210 of insulation covering being exposed to the lateral surfaces of the package.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications. Unless otherwise stated, “about,” “approximately,” or “substantially” preceding a value means+/−10 percent of the stated value. The term “couple” and variants thereof encompass both direct and indirect connections.

What is claimed is:

1. A wafer chip scale package (WCSP), comprising:
a die;
multiple electrically conductive terminals coupled to a first surface of the die; and
a metal covering abutting five surfaces of the die besides the first surface, each of the five surfaces of the die lying in a different plane.

2. The WCSP of claim 1, wherein the metal covering comprises a metallic ink residue.

3. The WCSP of claim 1, wherein the metal covering covers the entirety of the five surfaces of the die besides the first surface.

4. The WCSP of claim 1, wherein the metal covering has an approximate thickness of 750 A.

5. The WCSP of claim 1, wherein the metal covering is composed of a metal selected from the group consisting of: aluminum, copper, gold, titanium, nickel, silver, palladium, and tin.

6. A wafer chip scale package (WCSP), comprising:
a die having multiple surfaces, each of the multiple surfaces lying in a different plane;
multiple electrically conductive terminals coupled to a first of the multiple surfaces of the die;
an insulation covering in direct contact with five of the multiple surfaces of the die besides the first surface; and
a metal covering in direct contact with five surfaces of the insulation covering, each of the five surfaces of the insulation covering lying in a different plane.

7. The WCSP of claim 6, wherein the insulation covering covers the entirety of the five of the multiple surfaces of the die besides the first surface.

8. The WCSP of claim 6, wherein the metal covering covers the entirety of the five surfaces of the insulation covering.

9. The WCSP of claim 6, wherein the metal covering comprises a metal selected from the group consisting of: aluminum, copper, gold, titanium, nickel, silver, palladium, and tin.

10. The WCSP of claim 6, wherein the metal covering has an approximate thickness of 750 A.

11. The WCSP of claim 6, wherein the insulation covering comprises epoxy or silicon oxynitride (SiON).

12. The WCSP of claim 6, wherein the insulation covering has an approximate thickness of 750 A.

13. A method of manufacturing a wafer chip scale package (WCSP), comprising:
positioning multiple electrically conductive terminals on a surface of a semiconductor wafer;
positioning the semiconductor wafer on an adhesive layer such that the multiple electrically conductive terminals are in contact with the adhesive layer;
singulating the semiconductor wafer to produce a die, the die having at least one of the multiple electrically conductive terminals coupled to a first surface of the die; and
covering five surfaces of the die, besides the first surface of the die, with a metal covering, each of the five surfaces lying in a different plane.

14. The method of claim 13, wherein the metal covering has an approximate thickness of 750 A.

15. The method of claim 13, wherein the metal covering comprises a metal selected from the group consisting of: aluminum, copper, gold, titanium, nickel, silver, palladium, and tin.

16. The method of claim 13, further comprising covering the five surfaces of the die with an insulation covering, the insulation covering covered by the metal covering, the five surfaces of the die covered by the metal covering.

17. The method of claim 16, wherein covering the five surfaces of the die with the insulation covering comprises using a spray technique or a deposition technique.

18. The method of claim 13, wherein the insulation covering has an approximate thickness of 750 A.

19. The method of claim 13, wherein the singulating produces a space between the die and an immediately adjacent die, and further comprising expanding a width of the space prior to covering the five surfaces of the die with the metal covering.

20. The method of claim 13, wherein covering the five surfaces of the die with the metal covering comprises using a sputtering technique, a deposition technique, an electro-less plating technique, a spray technique, or a printing technique.
